(19) United States
(12) Patent Application Publication
(10) Pub. No.: US 2026/0303023 A1
(43) Pub. Date: Oct. 1, 2026

(54) ADAPTIVE BIASING IN A POWER AMPLIFIER CIRCUIT

(71) Applicant: Qorvo US, Inc., Greensboro, NC (US)

(72) Inventors: Alberto Costantini, Phoenix, AZ (US); Nadim Khlat, Ceret (FR)

(21) Appl. No.: 19/475,865

(22) PCT Filed: Apr. 8, 2024
(86) PCT No.: PCT/US2024/023572

§ 371 Date: Oct. 16, 2025

Related U.S. Application Data
(60) Provisional application No. 63/499,827, filed on May 3, 2023.

(51) Int. Cl. H03F 1/02; H03F 3/195; H03F 3/24

(52) U.S. Cl. CPC H03F 1/0222; H03F 3/195; H03F 3/245; H03F 2200/451

(57) ABSTRACT

Adaptive biasing in a power amplifier circuit is disclosed. The power amplifier circuit is configured to amplify a radio frequency (RF) signal based on a modulated voltage. Typically, the modulated voltage is generated based on a preestablished lookup table (LUT) that correlates amplitude and phase of the modulated voltage with a time-variant power envelope of the RF signal. In embodiments disclosed herein, an adaptive bias circuit can be dynamically activated to inject an adaptive bias current into a bias circuit in the power amplifier circuit to thereby reshape amplitude-amplitude (AM/AM) and/or amplitude-phase (AM/PM) characteristics of the modulated voltage. As a result, it is possible to dynamically adjust AM/AM gain dispersion and/or improve non-linear portions of the AM/PM characteristics of the modulated voltage to thereby improve performance of the power amplifier circuit.

### RELATED APPLICATIONS

This application claims the benefit of U.S. provisional patent application Ser. No. 63/499,827, filed on May 3, 2023, the disclosure of which is hereby incorporated herein by reference in its entirety.

### FIELD OF THE DISCLOSURE

The technology of the disclosure relates generally to a power amplifier circuit.

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

A fifth generation (5G) wireless communication system is widely regarded as a technological advancement that can achieve significantly higher data throughput, improved coverage range, enhanced signaling efficiency, and reduced latency compared to an existing fourth generation (4G) communication system like long-term evolution (LTE). Today, a mobile communication device is usually configured to support both 4G and 5G wireless communication systems. Often times, the mobile communication device needs to transmit and receive a radio frequency (RF) signal(s) in an RF spectrum that is more susceptible to propagation attenuation and interference that can result in substantial reduction in data throughput. To help mitigate propagation attenuation and maintain desirable data throughput, the mobile communication device typically employs a power amplifier(s) to boost output power of the RF signal(s) before transmission.

Envelope tracking (ET) and average power tracking (APT) are power management techniques designed to improve operating efficiency of the power amplifier(s). Specifically, the power amplifier(s) is configured to amplify the RF signal(s) based on a modulated voltage (ET voltage or APT voltage) that closely tracks a time-variant power envelope of the RF signal(s). Understandably, the closer the modulated voltage resembles amplitude and phase of the time-variant envelope, the better the power amplifier(s) can perform to help improve overall performance, such as adjacent channel leakage ratio (ACLR) and adjacent channel power ratio (ACPR), of the mobile communication device.

### SUMMARY

Aspects disclosed in the detailed description include adaptive biasing in a power amplifier circuit. The power amplifier circuit is configured to amplify a radio frequency (RF) signal based on a modulated voltage. Typically, the modulated voltage is generated based on a preestablished lookup table (LUT) that correlates amplitude and phase of the modulated voltage with a time-variant power envelope of the RF signal. In embodiments disclosed herein, an adaptive bias circuit can be dynamically activated to inject an adaptive bias current into a bias circuit in the power amplifier circuit to thereby reshape amplitude-amplitude (AM/AM) and/or amplitude-phase (AM/PM) characteristics of the modulated voltage. As a result, it is possible to dynamically adjust AM/AM gain dispersion and/or improve non-linear portions of the AM/PM characteristics of the modulated voltage to thereby improve performance of the power amplifier circuit.

In one aspect, a power amplifier apparatus is provided. The power amplifier apparatus includes a current source. The current source is configured to generate a low-frequency current. The power amplifier apparatus also includes a power amplifier circuit. The power amplifier circuit includes a bias circuit. The bias circuit is configured to generate a bias voltage based on the low-frequency current. The power amplifier circuit also includes an output stage. The output stage is biased by the bias voltage to amplify an RF signal based on a modulated voltage. The power amplifier apparatus also includes an adaptive bias circuit. The adaptive bias circuit is coupled to the bias circuit. The adaptive bias circuit is configured to inject an adaptive bias current into the bias circuit to dynamically adjust one or more of an AM/AM characteristic and an AM/PM characteristic of the modulated voltage.

In another aspect, a wireless device is provided. The wireless device includes a wireless transmission circuit. The wireless transmission circuit includes a power management integrated circuit (PMIC). The PMIC is configured to generate a modulated voltage based on a preestablished lookup table (LUT) that correlates a time-variant target voltage with the modulated voltage. The wireless transmission circuit also includes a power amplifier apparatus. The power amplifier apparatus includes a current source. The current source is configured to generate a low-frequency current. The power amplifier apparatus also includes a power amplifier circuit. The power amplifier circuit includes a bias circuit. The bias circuit is configured to generate a bias voltage based on the low-frequency current. The power amplifier circuit also includes an output stage. The output stage is biased by the bias voltage to amplify an RF signal based on the modulated voltage. The power amplifier apparatus also includes an adaptive bias circuit. The adaptive bias circuit is coupled to the bias circuit. The adaptive bias circuit is configured to inject an adaptive bias current into the bias circuit to dynamically adjust one or more of an AM/AM characteristic and an AM/PM characteristic of the modulated voltage.

In another aspect, a method for enabling adaptive biasing in a power amplifier circuit is provided. The method includes generating a low-frequency current. The method also includes generating a bias voltage based on the low-frequency current. The method also includes using the bias voltage to bias an output stage in the power amplifier circuit to thereby amplify an RF signal based on a modulated voltage. The method also includes injecting an adaptive bias current into the power amplifier circuit to dynamically adjust one or more of an AM/AM characteristic and an AM/PM characteristic of the modulated voltage.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure and, together with the description, serve to explain the principles of the disclosure.

FIG. 1 is a schematic diagram of an exemplary existing wireless transmission circuit wherein a power management integrated circuit (PMIC) generates a modulated voltage from a preestablished lookup table (LUT);

FIGS. 2A and 2B are graphic diagrams providing exemplary illustrations of amplitude-amplitude (AM/AM) and amplitude-phase (AM/PM) characteristics of the modulated voltage generated by the PMIC in FIG. 1;

FIG. 3 is a schematic diagram of an exemplary power amplifier apparatus configured according to one embodiment of the present disclosure to adjust AM/AM and/or AM/PM characteristics of a modulated voltage;

FIGS. 4A-4C are graphic diagrams providing exemplary illustrations of AM/AM, AM/PM, and adjacent channel leakage ratio (ACLR) improvements that can be achieved by the power amplifier circuit of FIG. 3;

FIG. 5 is a graphic diagram providing an exemplary illustration of multiple gain dispersion regions wherein the power amplifier circuit of FIG. 3 can operate;

FIG. 6 is a schematic diagram of an exemplary power amplifier apparatus configured according to another embodiment of the present disclosure;

FIG. 7 is a schematic diagram of a wireless transmission circuit that can be configured to include the power amplifier apparatuses of FIGS. 3 and 6;

FIG. 8 is a schematic diagram of an exemplary communication device wherein the wireless transmission circuit of FIG. 7 can be provided; and

FIG. 9 is a flowchart of an exemplary process for enabling adaptive biasing in the power amplifier apparatuses of FIGS. 3 and 6.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include adaptive biasing in a power amplifier circuit. The power amplifier circuit is configured to amplify a radio frequency (RF) signal based on a modulated voltage. Typically, the modulated voltage is generated based on a preestablished lookup table (LUT) that correlates amplitude and phase of the modulated voltage with a time-variant power envelope of the RF signal. In embodiments disclosed herein, an adaptive bias circuit can be dynamically activated to inject an adaptive bias current into a bias circuit in the power amplifier circuit to thereby reshape amplitude-amplitude (AM/AM) and/or amplitude-phase (AM/PM) characteristics of the modulated voltage. As a result, it is possible to dynamically adjust AM/AM gain dispersion and/or improve non-linear portions of the AM/PM characteristics of the modulated voltage to thereby improve performance of the power amplifier circuit.

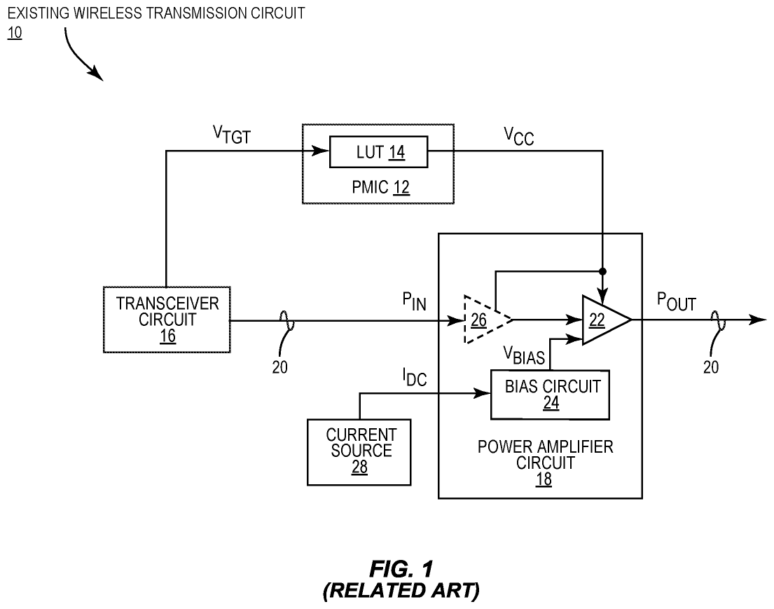

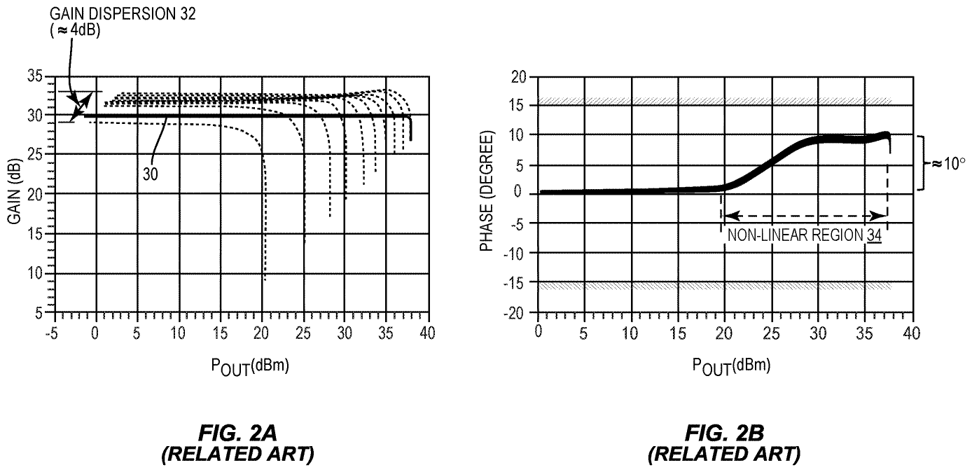

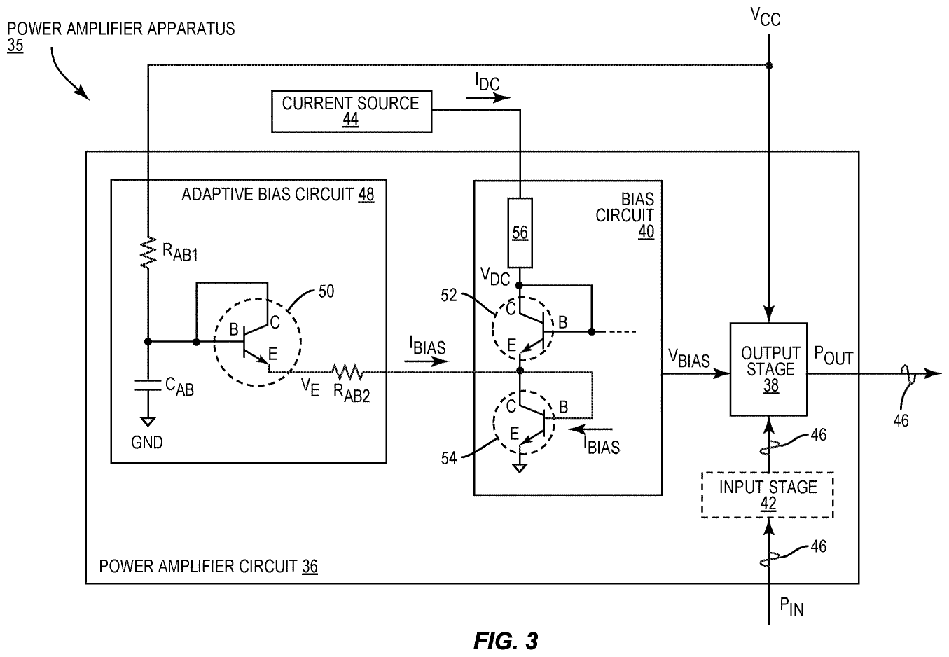

Before discussing the power amplifier circuit of the present disclosure, starting at FIG. 3, a brief overview of an existing wireless transmission circuit is first provided with reference to FIGS. 1 and 2A-2B to help establish the technical problems to be solved by embodiments of the present disclosure.

FIG. 1 is a schematic diagram of an exemplary existing wireless transmission circuit 10 wherein a power management integrated circuit (PMIC) 12 is configured to generate a modulated voltage V_{CC}, such as an envelope tracking (ET) voltage, from a preestablished lookup table (LUT) 14. The existing wireless transmission circuit 10 typically includes a transceiver circuit 16 and a power amplifier circuit 18. The power amplifier circuit 18 is configured to amplify an RF signal 20, which is generated by the transceiver circuit 16, based on the modulated voltage V_{CC}.

The power amplifier circuit 18 typically includes an output stage 22 and a bias circuit 24. In addition, the power amplifier circuit 18 may also include an input stage 26. The output stage 22 and the input stage 26, if available, are configured to amplify the RF signal 20 from an input power P_{IN} to an output power P_{OUT} based on the modulated voltage V_{CC}.

The output stage 22 can include various transistors (not shown), such as bipolar junction transistors (BJTs) or heterojunction bipolar transistors (HBTs), that operate based on a bias voltage V_{BIAS}. Typically, the bias circuit 24 is configured to generate the bias voltage V_{BIAS} based on a low-frequency current I_{DC} (e.g., a direct current) provided by an external current source 28.

The transceiver circuit 16 is configured to generate a modulated target voltage V_{TGT} that closely tracks the input power both in amplitude and phase. The preestablished LUT 14 is typically pre-calibrated to correlate the modulated target voltage V_{TGT} with the modulated voltage V_{CC}. In this regard, for an instantaneous value (or a range of the instantaneous value) of the modulated target voltage V_{TGT}, the PMIC 12 can simply retrieve a set of corresponding amplitude and phase values from the preestablished LUT 14 and generate the modulated voltage V_{CC} accordingly.

Conventionally, the preestablished LUT 14 is determined based on a so-called “waterfall” characterization that sweeps through the output power P_{OUT} and the modulated voltage V_{CC}. A specific value in the preestablished LUT 14 is typically calculated from the waterfall characterization based on respective reference points of the modulated voltage V_{CC} and the output power P_{OUT} (e.g., V_{CC}=3.5 V or 3.8 V and P_{OUT}=+10 dBm) and a target power amplifier compression point. Each entry in the preestablished LUT 14 is associated with an AM/AM characterization and an AM/PM characterization, which are illustrated in FIGS. 2A and 2B, respectively.

FIG. 2A is a graphic diagram illustrating the AM/AM characterization of the preestablished LUT 14. Herein, the AM/AM characterization is represented by a constant gain 30 (a.k.a. IsoGain) obtained by sweeping the output power P_{OUT} across a gain dispersion region 32. As illustrated, the gain dispersion region 32 is approximately four decibels (4 dB).

FIG. 2B is a graphic diagram illustrating the AM/PM characterization of the preestablished LUT 14. Herein, the AM/PM characterization typically refers to a non-linear region 34, wherein the AM/PM characteristic is a non-linear function of the output power P_{OUT}. As illustrated, the non-linear phase changes approximately ten degrees (10°) when the output power Pour changes from 20 dBm to 35 dBm.

With reference back to FIG. 1, conventionally, the transceiver circuit 16 is configured to correct, or at least mitigate, the non-linear AM/PM characteristic through digital pre-distortion (DPD). Understandably, the larger the AM/PM changes in the non-linear region 34, the more difficult it is to correct the non-linear AM/PM characteristic through DPD as the complex coefficients involved in DPD can grow significantly. As such, it is desirable to reduce the AM/PM changes (i.e., flatten the AM/PM curve in FIG. 2B) in the non-linear region 34 to help reduce complexity of the DPD operation. Also, as an important figure-of-merit (FoM) of ET, it is further desired to widen the gain dispersion region 32 in FIG. 2A. In context of the present disclosure, reshaping AM/AM characteristic refers to a widening of the gain dispersion region 32, whereas reshaping AM/PM characteristic refers to a flattening of the AM/PM curve in the non-linear region 34. Unfortunately, the modulated voltage V_{CC} as generated based on the preestablished LUT 14 allows very little adjustment and/or shaping of the AM/AM and AM/PM characteristics. Hence, the technical problem that needs to be solved is how to dynamically adjust the AM/AM characteristic to widen the gain dispersion region 32 and reshape the AM/PM characteristic to help improve the effectiveness of DPD, particularly in the context of ET.

In this regard, FIG. 3 is a schematic diagram of an exemplary power amplifier apparatus 35 that can be configured according to one embodiment of the present disclosure to adjust AM/AM and/or AM/PM characteristics of a modulated voltage V_{CC}. In a non-limiting example, the modulated voltage V_{CC} can be an ET voltage. Herein, the power amplifier apparatus 35 includes a power amplifier circuit 36. In an embodiment, the power amplifier circuit 36 includes an output stage 38, a bias circuit 40, and may further include an input stage 42. The output stage 38 is biased by a bias voltage V_{BIAS} and the bias circuit 40 is configured to generate the bias voltage V_{BIAS} based on a low-frequency current I_{DC} (e.g., a direct current) provided by an external current source 44. The output stage 38 and the input stage 42, if available, are configured to amplify an RF signal 46 from an input power P_{IN} to an output power P_{OUT} based on the modulated voltage V_{CC}.

Like in the existing wireless transmission circuit 10 of FIG. 1, the modulated voltage V_{CC} may be generated by the PMIC 12 based on the preestablished LUT 14. As such, the modulated voltage V_{CC} will inherently exhibit the AM/AM and AM/PM characteristics as illustrated in FIGS. 2A and 2B.

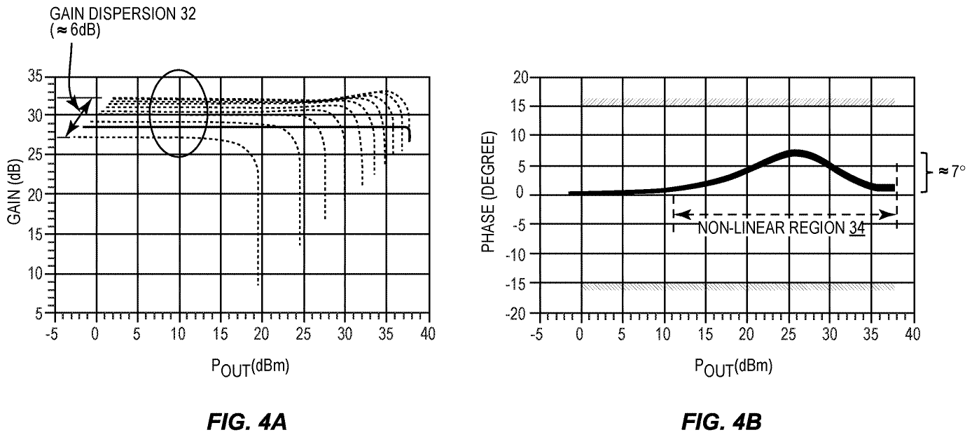

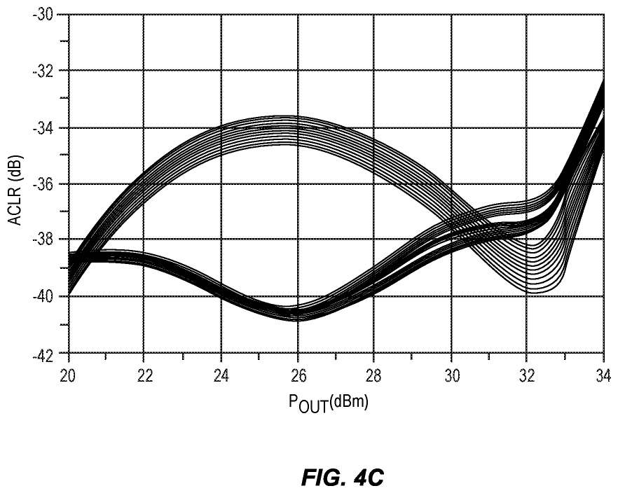

In this regard, to solve the technical problem associated with the existing wireless transmission circuit 10, the power amplifier circuit 36 is configured herein to further include an adaptive bias circuit 48. The adaptive bias circuit 48 is configured to inject an adaptive bias current I_{BIAS} into the bias circuit 40 to dynamically adjust one or more inherent characteristics (e.g., the AM/AM characteristic and/or the AM/PM characteristic) of the modulated voltage V_{CC}. As a result, as illustrated later in FIGS. 4A-4C, the power amplifier circuit 36 is able to provide significant improvement with respective to AM/AM gain dispersion, non-linear phase change, and ACLR performance.

In an embodiment, the adaptive bias circuit 48 includes a bias transistor 50, which can be an HBT, as an example. The bias transistor 50 has a base electrode (B), a collector electrode (C), and an emitter electrode (E). The base electrode (B) is configured to receive the modulated voltage V_{CC} via a first bias resistor R_{AB1}, which may be a fixed or an adjustable resistor. The base electrode (B) is also coupled to a ground (GND) via a bias capacitor C_{AB}. In an embodiment, the bias capacitor C_{AB} may filter out residual RF content in the modulated voltage V_{CC}. The collector electrode (C) is coupled to the base collector (B).

The bias circuit 40 includes a pair of transistors 52, 54, each having a respective base electrode (B), a respective collector electrode (C), and a respective emitter electrode (E). The collector electrode (C) of the transistor 52 is coupled to the external current source 44 via a voltage divider network 56. The voltage divider network 56 is coupled to the external current source 44 to receive the low-frequency current loc and output a corresponding low-frequency voltage V_{DC} to the collector electrode (C) of the transistor 52. The emitter electrode (E) of the transistor 52 is coupled to the collector electrode (C) of the transistor 54, which is further coupled to the base electrode (B) of the transistor 54. The emitter electrode (E) of the transistor 54 is coupled to the ground (GND). In an embodiment, the emitter electrode (E) of the bias transistor 50 is configured to output the bias current IBIAS to the base electrode (B) of the transistor 54 via a second bias resistor R_{AB2}. Notably, the bias circuit 40 can include additional components like transistors, resistors, capacitors, and/or voltage supplies to generate the bias voltage V_{BIAS}. These additional components are omitted herein for the sake of simplicity.

In the adaptive bias circuit 48, the base electrode (B) of the bias transistor 50 can be seen as biased by the modulated voltage V_{CC}. In a non-limiting example, the transistor 54 in the bias circuit 40 sets an emitter voltage V_{E} at the emitter electrode (E) of the bias transistor 50 at approximately 1.25 V. In this regard, when the modulated voltage V_{CC} is higher than or equal to a threshold voltage of the bias transistor 50, the bias transistor 50 (and therefore the adaptive bias circuit 48) will be automatically turned on (i.e., activated). In contrast, the bias transistor 50 (and therefore the adaptive bias circuit 48) will be automatically turned off (i.e., deactivated) when the modulated voltage V_{CC} is lower than the threshold voltage of the bias transistor 50.

In one alternative embodiment, the bias transistor 50 may be replaced by a Schottky diode. Accordingly, the adaptive bias circuit 48 will be automatically activated when the modulated voltage V_{CC} is higher than or equal to approximately 2 V and deactivated when the modulated voltage V_{CC} is below 2 V. In another alternative embodiment, the bias transistor 50 may be connected to a Schottky diode. Accordingly, the adaptive bias circuit 48 will be automatically activated when the modulated voltage V_{CC} is higher than or equal to approximately 3.2 V and deactivated when the modulated voltage V_{CC} is below 3.2 V.

The first bias resistor R_{AB1} and the second bias resistor R_{AB2} may be adjusted, either statically or dynamically, to control an amount of the bias current I_{BIAS} to be injected into the bias circuit 40. In other words, the first bias resistor R_{AB1} and/or the second bias resistor R_{AB2} may be adjusted to control a slope (i.e., change rate versus the modulated voltage V_{CC}) of the bias current I_{BIAS}. In a preferred embodiment, the first bias resistor R_{AB1} may be adjusted to control the slope of the bias current I_{BIAS}, while the second bias resistor R_{AB2} may be used to maintain a larger resistance to minimize leakage and noise injection into the bias circuit 40. Given that the bias current I_{BIAS} is solely driven by the modulated voltage V_{CC}, the threshold voltage of the bias transistor 50, the first bias resistor R_{AB1}, and/or the second bias resistor R_{AB2}, the bias current I_{BIAS} is independent from the low-frequency current loc provided by the external current source 44.

The power amplifier circuit 36 can provide significant improvement over the existing wireless transmission circuit 10 of FIG. 1 in many aspects. FIGS. 4A-4C are graphic diagrams providing exemplary illustrations of AM/AM, AM/PM, and adjacent channel leakage ratio (ACLR) improvements that can be achieved by the power amplifier circuit 36 of FIG. 3.

As illustrated in FIG. 4A, by dynamically injecting the bias current I_{BIAS} into the bias circuit 40, the gain dispersion region 32 is widened from approximately 4 dB in FIG. 2A to approximately 6 dB herein. As illustrated in FIG. 4B, the non-linear phase change in the non-linear region 34 is reduced from approximately 10° in FIG. 2B to approximately 7° herein. As illustrated in FIG. 4C, the power amplifier circuit 36 is able to reduce ACLR to approximately −41 dBm. Thus, by adding the adaptive bias circuit 48, it is possible to solve the technical problems associated with the existing wireless transmission circuit 10 of FIG. 1.

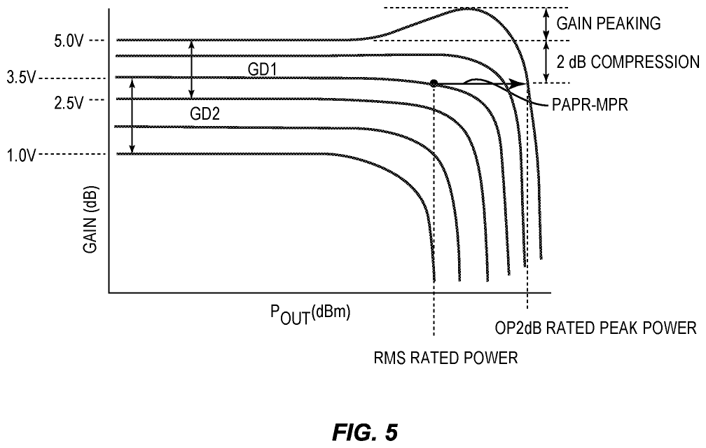

As mentioned earlier, the adaptive bias circuit 48 may be configured to be turned on and off based on different threshold voltages. This makes it possible for the power amplifier circuit 36 to operate in different gain dispersion regions. FIG. 5 is a graphic diagram providing an exemplary illustration of multiple gain dispersion regions GD1, GD2 wherein the power amplifier circuit 36 of FIG. 2 can be configured to operate.

Herein, the gain dispersion region GD1 is defined by a gain differential between 2.5 V and 5 V of the modulated voltage V_{CC}, and the gain dispersion region GD2 is defined by a gain differential between 1 V and 3.5 V of the modulated voltage V_{CC}. Studies have shown that, with the adaptive bias circuit 48, the power amplifier circuit 36 is able to operate in the gain dispersion regions GD1, GD2 with satisfactory performance. In particular, the power amplifier circuit 36 is able to reduce AM/AM distortion from 1.5 dB to less than 1 dB in the gain dispersion region GD1.

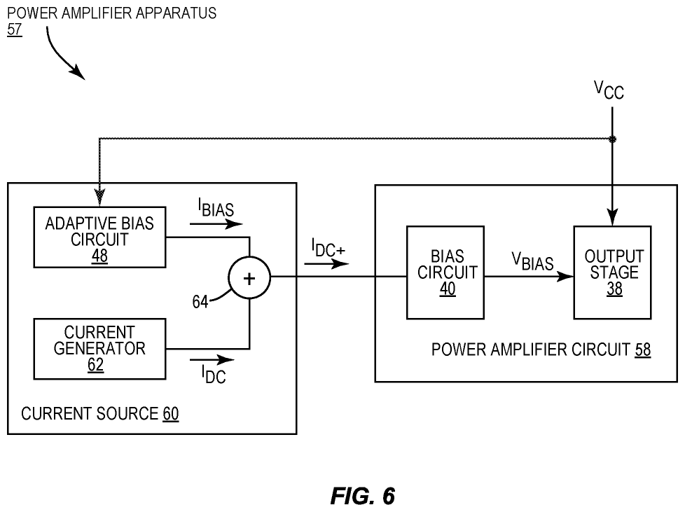

With reference back to FIG. 3, alternative to incorporating the adaptive bias circuit 48 into the power amplifier circuit 36, it is also possible to provide the adaptive bias circuit 48 in the external current source 44. In this regard, FIG. 6 is a schematic diagram of an exemplary power amplifier apparatus 57 configured according to another embodiment of the present disclosure. Common elements between FIGS. 3 and 6 are shown therein with common element numbers and will not be re-described herein.

Herein, the power amplifier apparatus 57 includes a power amplifier circuit 58. In an embodiment, the power amplifier circuit 58 includes the output stage 38 and the bias circuit 40, whereas the adaptive bias circuit 48 is provided in an external current source 60. In an embodiment, the external current source 60 may include a current generator 62 that generates the low-frequency current I_{DC} and a combiner 64 that combines the low-frequency current I_{DC} with the bias current I_{BIAS} to generate a combined low-frequency current I_{DC+} and injects the combined low-frequency current I_{DC+} into the bias circuit 40. By separating the adaptive bias circuit 48 from the power amplifier circuit 58, it may provide more degrees of freedom in terms of dynamically shaping the combined low-frequency current I_{DC+} as a function of the modulated voltage V_{CC}.

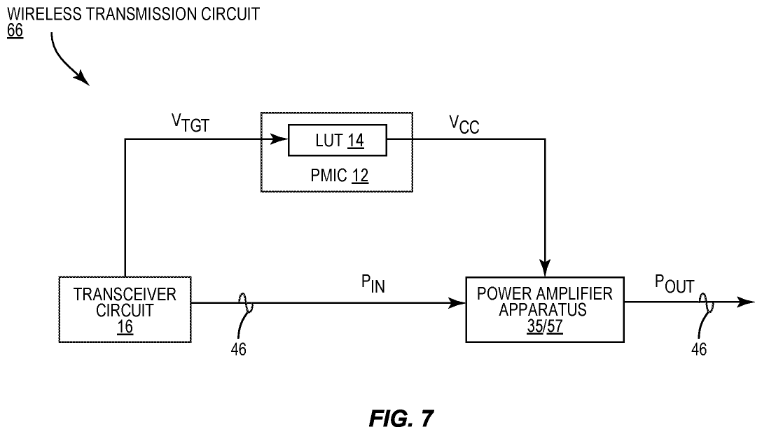

The power amplifier apparatus 35 of FIG. 3 and the power amplifier apparatus 57 of FIG. 6 may replace the power amplifier circuit 18 to help improve overall performance of the existing wireless transmission circuit 10. In this regard, FIG. 7 is a schematic diagram of an exemplary wireless transmission circuit 66 wherein the power amplifier apparatus 35 of FIG. 3 and the power amplifier apparatus 57 of FIG. 6 can be provided. Common elements between FIGS. 3, 6, and 7 are shown therein with common element numbers and will not be re-described herein.

Herein, the wireless transmission circuit 66 reuses the PMIC 12 and the transceiver circuit 16 in the existing wireless transmission circuit 10, only replacing the power amplifier circuit 18 with either the power amplifier apparatus 35 or the power amplifier apparatus 57. As such, the wireless transmission circuit 66 can achieve a higher degree of backward compatibility and component reuse.

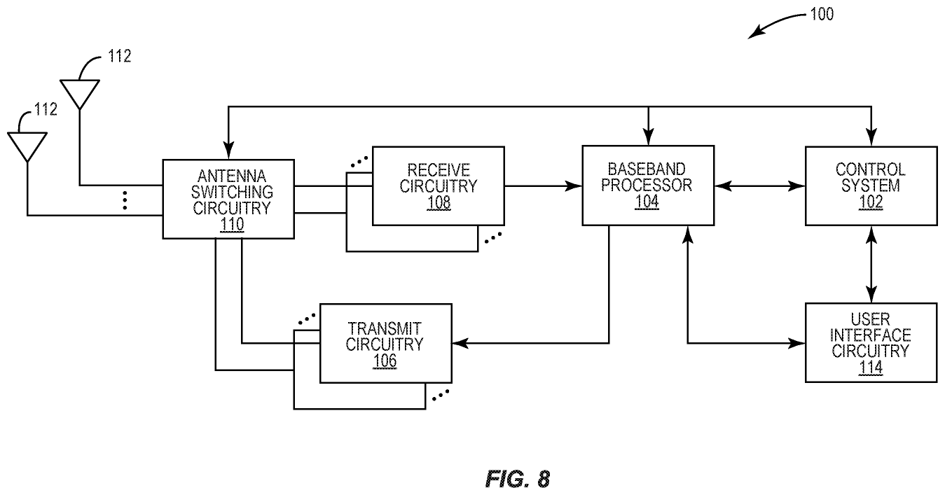

The wireless transmission circuit 66 of FIG. 7 can be provided in a communication device to support the embodiments described above. In this regard, FIG. 8 is a schematic diagram of an exemplary communication device 100 wherein the wireless transmission circuit 66 of FIG. 7 can be provided.

Herein, the communication device 100 can be any type of communication device, such as mobile terminal, smart watch, tablet, computer, navigation device, access point, base station (e.g., eNB, gNB, etc.), and any other wireless communication device that supports wireless communications, such as cellular, wireless local area network (WLAN), Bluetooth, Ultra-wideband (UWB), and near field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

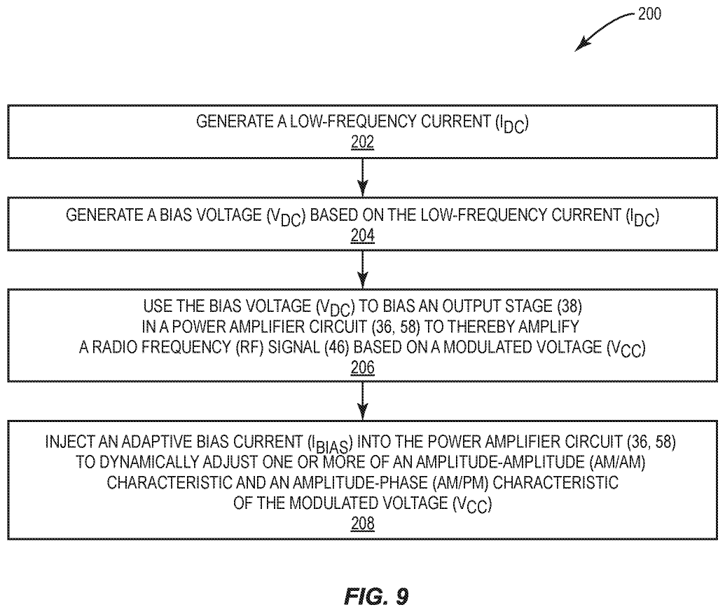

In an embodiment, the power amplifier apparatus 35 of FIG. 3 and the power amplifier apparatus 57 of FIG. 6 can be configured to enable adaptive biasing based on a process. In this regard, FIG. 9 is a flowchart of an exemplary process 200 for enabling adaptive biasing in the power amplifier apparatus 35 of FIG. 3 and the power amplifier apparatus 57 of FIG. 6.

Herein, the process 200 includes generating the low-frequency current I_{DC} (step 202). The process 200 also includes generating the bias voltage V_{DC} based on the low-frequency current I_{DC} (step 204). The process 200 also includes using the bias voltage V_{DC} to bias the output stage 38 in the power amplifier circuit 36 or 58 to thereby amplify the RF signal 46 based on the modulated voltage V_{CC} (step 206). The process 200 also includes injecting the adaptive bias current I_{BIAS} into the power amplifier circuit 36 or 58 to dynamically adjust one or more of the AM/AM characteristic and the AM/PM characteristic of the modulated voltage V_{CC} (step 208).

Those skilled in the art will recognize improvements and modifications to the embodiments of the present disclosure. All such improvements and modifications are considered within the scope of the concepts disclosed herein and the claims that follow.

1. A power amplifier apparatus comprising:
a current source configured to generate a low-frequency current;
a power amplifier circuit comprising:
a bias circuit configured to generate a bias voltage based on the low-frequency current; and
an output stage biased by the bias voltage to amplify a radio frequency (RF) signal based on a modulated voltage; and
an adaptive bias circuit coupled to the bias circuit and configured to inject an adaptive bias current into the bias circuit to dynamically adjust one or more of an amplitude-amplitude (AM/AM) characteristic and an amplitude-phase (AM/PM) characteristic of the modulated voltage.

2. The power amplifier apparatus of claim 1, wherein the adaptive bias circuit comprises:
a bias transistor comprising:
a base electrode coupled to a first resistor and configured to receive the modulated voltage;
a collector electrode coupled to the base electrode; and
an emitter electrode coupled to the bias circuit via a second resistor; and
a bias capacitor coupled between the base electrode and a ground and configured to filter out residual RF content in the modulated voltage.

3. The power amplifier apparatus of claim 2, wherein the adaptive bias circuit is automatically activated in response to the modulated voltage being higher than or equal to a threshold voltage and deactivated in response to the modulated voltage being lower than the threshold voltage.

4. The power amplifier apparatus of claim 3, wherein the threshold voltage can be adjusted to cause the power amplifier circuit to operate in different gain dispersion regions.

5. The power amplifier apparatus of claim 2, wherein:
the first resistor can be adjusted to control a slope of the adaptive bias current; and
the second resistor can be adjusted to minimize leakage and/or noise injection into the bias circuit.

6. The power amplifier apparatus of claim 2, wherein the bias circuit comprises:
a voltage divider network coupled to the current source and configured to output a low-frequency voltage based on the low-frequency current;
a first transistor having a respective collector electrode coupled to the voltage divider network; a respective base electrode coupled to the respective collector electrode, and a respective emitter electrode coupled to the second resistor in the adaptive bias circuit; and
a second transistor having a respective collector electrode coupled to the second resistor in the adaptive bias circuit and the respective emitter electrode of the first transistor, a respective base electrode coupled to the respective collector electrode, and an emitter electrode coupled to the ground.

7. The power amplifier apparatus of claim 1, wherein the power amplifier circuit further comprises the adaptive bias circuit and the current source is external to the power amplifier circuit.

8. The power amplifier apparatus of claim 1, wherein the current source is external to the power amplifier circuit and comprises:
the adaptive bias circuit configured to generate the adaptive bias current;
a current generator configured to generate the low-frequency current; and
a combiner coupled to the bias circuit and configured to:
combine the adaptive bias current and the low-frequency current to generate a combined low-frequency current; and
inject the combined low-frequency current into the bias circuit.

9. A wireless device comprising a wireless transmission circuit comprising:
a power management integrated circuit (PMIC) configured to generate a modulated voltage based on a preestablished lookup table (LUT) that correlates a time-variant target voltage with the modulated voltage; and
a power amplifier apparatus comprising:
a current source configured to generate a low-frequency current; and
a power amplifier circuit comprising:
a bias circuit configured to generate a bias voltage based on the low-frequency current; and
an output stage biased by the bias voltage to amplify a radio frequency (RF) signal based on the modulated voltage; and
an adaptive bias circuit coupled to the bias circuit and configured to inject an adaptive bias current into the bias circuit to dynamically adjust one or more of an amplitude-amplitude (AM/AM) characteristic and an amplitude-phase (AM/PM) characteristic of the modulated voltage.

10. The wireless device of claim 9, further comprising a transceiver circuit configured to generate the RF signal and the time-variant target voltage.

11. The wireless device of claim 9, wherein the adaptive bias circuit comprises:
a bias transistor comprising:
a base electrode coupled to a first resistor and configured to receive the modulated voltage;
a collector electrode coupled to the base electrode; and
an emitter electrode coupled to the bias circuit via a second resistor; and
a bias capacitor coupled between the base electrode and a ground and configured to filter out residual RF content in the modulated voltage.

12. The wireless device of claim 11, wherein the adaptive bias circuit is automatically activated in response to the modulated voltage being higher than or equal to a threshold voltage and deactivated in response to the modulated voltage being lower than the threshold voltage.

13. The wireless device of claim 12, wherein the threshold voltage can be adjusted to cause the power amplifier circuit to operate in different gain dispersion regions.

14. The wireless device of claim 11, wherein:
the first resistor can be adjusted to control a slope of the adaptive bias current; and
the second resistor can be adjusted to minimize leakage and/or noise injection into the bias circuit.

15. The wireless device of claim 11, wherein the bias circuit comprises:
a voltage divider network coupled to the current source and configured to output a low-frequency voltage based on the low-frequency current;
a first transistor having a respective collector electrode coupled to the voltage divider network; a respective base electrode coupled to the respective collector electrode, and a respective emitter electrode coupled to the second resistor in the adaptive bias circuit; and
a second transistor having a respective collector electrode coupled to the second resistor in the adaptive bias circuit and the respective emitter electrode of the first transistor, a respective base electrode coupled to the respective collector electrode, and an emitter electrode coupled to the ground.

16. The wireless device of claim 9, wherein the power amplifier circuit further comprises the adaptive bias circuit and the current source is external to the power amplifier circuit.

17. The wireless device of claim 9, wherein the current source is external to the power amplifier circuit and comprises:
the adaptive bias circuit configured to generate the adaptive bias current;
a current generator configured to generate the low-frequency current; and
a combiner coupled to the bias circuit and configured to:
combine the adaptive bias current and the low-frequency current to generate a combined low-frequency current; and
inject the combined low-frequency current into the bias circuit.

18. A method for enabling adaptive biasing in a power amplifier circuit comprising:
generating a low-frequency current;
generating a bias voltage based on the low-frequency current;
using the bias voltage to bias an output stage in the power amplifier circuit to thereby amplify a radio frequency (RF) signal based on a modulated voltage; and
injecting an adaptive bias current into the power amplifier circuit to dynamically adjust one or more of an amplitude-amplitude (AM/AM) characteristic and an amplitude-phase (AM/PM) characteristic of the modulated voltage.

19. The method of claim 18, further comprising:
automatically injecting the adaptive bias current into the power amplifier circuit when the modulated voltage is higher than or equal to a threshold voltage; and
automatically stopping injecting the adaptive bias current into the power amplifier circuit when the modulated voltage is lower than the threshold voltage.

20. The method of claim 19, further comprising adjusting the threshold voltage to cause the power amplifier circuit to operate in different gain dispersion regions.
